(19) United States
(12) Patent Application Publication
(10) Pub. No.: US 2023/0037971 A1
(43) Pub. Date: Feb. 9, 2023

(54) INTERFEROMETRIC GAIN LASER DEVICE

(71) Applicant: ADIGE S.P.A., Levico Terme (Trento) (IT)

(72) Inventors: Sara PICCIONE, Pergine Valsugana (Trento) (IT); Stefano BIASI, Sfruz (Trento) (IT); Lorenzo PAVESI, Trento (IT); Cristiano RAFFALDI, Verona (IT)

(21) Appl. No.: 17/795,272

(22) PCT Filed: Feb. 1, 2021
(86) PCT No.: PCT/IB2021/050782

§ 371 Date: Jul. 26, 2022

(30) Foreign Application Priority Data
Jan. 31, 2020 (IT) 102020000001897

(51) Int. Cl. H01S 5/14; H01S 3/083; H01S 3/081

(52) U.S. Cl. CPC H01S 5/14; H01S 3/083; H01S 3/0813; H01S 3/0811

(57) ABSTRACT

A laser device configured to emit a coherent optical radiation is provided. The laser device has an amplifier system having a single interferometric optical amplification arrangement or a plurality of interferometric optical amplification arrangements in series, an optical return path of an optical beam emerging from the amplifier system and entering the amplifier system to form an optical ring resonant structure, and a radiation output for extracting a portion of the optical beam emerging from the amplifier system and deliver the extracted portion of the optical beam emerging from the amplifier system as output laser radiation of the laser device.

This invention relates to laser devices, particularly, but not exclusively, semiconductor laser devices.

One of the main limitations of this particular class of laser is the impossibility of attaining a high optical power, higher than a few tens of watts, for example on the order of kilowatts or higher, from a single laser diode.

This power is necessary in certain industrial processes, for example in the industrial processing of materials and of metal plates and profiles in particular, where the laser is used as a thermal tool for a large variety of applications that depend on the interaction parameters of the laser beam with the material being processed, specifically the energy density per volume of incidence of the laser beam on the material, and the interaction time interval.

For example, by directing a low energy density (on the order of tens of W per mm² of surface) for a prolonged time (on the order of seconds) on a metal material, a hardening process is carried out, whereas by directing a high energy density (on the order of tens of MW per mm² of surface) for a time on the order of femtoseconds or picoseconds on the same metal material, a photo-ablation process is carried out. In the intermediate range of increasing energy density and decreasing processing time, the control of these parameters allows welding, cutting, drilling, engraving, and marking processes to be carried out.

A laser device is also used in additive processes where the material is, for example, supplied in the form of a filament, or in the form of powder emitted by a nozzle, or alternatively it may be present in the form of a powder bed, and is therefore melted by laser radiation, obtaining a three-dimensional print following the re-solidification of said material.

In the prior art, to obtain high optical powers on the orders of magnitude referred to above, the combination of different laser beams is used.

Different laser beams may be combined through different techniques based on respective associations of laser-emitting devices, such as combining beams that are incoherent with each other (incoherent combination), combining beams in wavelength, and combining beams that are coherent with each other (coherent combination).

Disadvantageously, through incoherent beam combination a total beam is obtained, the radiance of which (magnitude which takes into account both the total optical power and the resulting beam quality) does not exceed the radiance of the single laser. Furthermore, in incoherent combination techniques there is no relationship (neither phase nor spectral) between the beams involved, and thus the optical power increases with the increase in the number of laser-emitting devices involved at the expense of the quality of the overall beam obtained.

Through wavelength beam combination or coherent beam combination it is possible to increase the optical power emitted, while keeping the quality of the resulting beam unchanged, the radiance increasing linearly with the number of combined laser-emitting devices.

In particular, in the wavelength beam combination technique each laser-emitting device operates at a different wavelength and the use of a dispersive optical element allows the superimposition of the beams to be combined. The increase in power is therefore obtained at the expense of the spectral quality of the beam.

On the other hand, in an architecture for coherent beam combination, all the laser-emitting devices operate at the same wavelength and a specific phase relationship exists so that constructive interference may occur between the individual beams.

The use of one of the techniques referred to depends on the application for which a high optical power is required.

In order to create a high-brilliance source, for example of the type used in the laser processing of materials, it is necessary to adopt architectures for wavelength or coherent beam combination. Among these, currently the most frequent solution is the former, and the main reason is to be attributed to its greater ease of implementation. In effect, since these are techniques that combine different laser beams, i.e., beams delivered by different laser-emitting devices, the main difficulty in creating an architecture for coherent beam combination lies in the active control of the phase relationship necessary to obtain constructive interference between the various beams involved.

This difficulty becomes even greater for semiconductor laser devices, where thermal instabilities and non-linear phenomena may significantly alter the phase of the beam.

This invention has the object of providing an alternative solution to existing architectures of laser devices and systems, which is simple to manufacture and capable of emitting a coherent beam of high optical power.

In particular, this invention has the object of providing a robust and simple-to-manufacture laser device, which allows the maximum power that may be extracted from a semiconductor laser to be increased with respect to the prior art.

According to this invention, this object is achieved by a laser device having the features set out in claim 1.

Particular embodiments form the subject matter of the dependent claims, the content of which is to be understood as an integral part of this description.

In summary, this invention is based on the arrangement of an optical amplifier system, i.e., of optical gain means, in a single optical resonant structure, such as a resonant cavity (including also a Fabry-Perot cavity) or an optical ring path, whereby the laser device of the invention consists of a single emitting device and not a combination of a plurality of emitting devices. The gain means comprise a stage or a plurality of amplifier stages in series or cascaded, each of which includes an interferometric optical amplification arrangement, i.e., an optical arrangement which first accomplishes the division of an incident optical beam into a pair of secondary beams, then conducts the two secondary beams respectively through an amplification branch and an unperturbed propagation branch, i.e., without amplification, and finally combines them in an interference beam. The division of the incident optical beam is accomplished in such a way that most of the power of the incident beam is directed toward the non-amplifying propagation branch.

In a currently preferred embodiment, the amplification branch comprises a semiconductor optical amplifier, powered by an injection current to obtain a population inversion condition of the charge carriers confined in the active region where the consequent radiative recombination and coherent photon emission occurs in phase with the passing photons of the incident optical beam. Advantageously, splitting the beam allows the power entering the semiconductor optical amplifier to be reduced. With the same injection current, with respect to a standard amplifier, various problems relating to the circulating power are resolved, such as damage to the surface of the semiconductor, thermal problems associated with any power absorption, and non-linear phenomena. This configuration allows for a device with greater reliability and a longer average life to be obtained.

An optical path returning the interference beam to the input of the gain means forms a resonant structure with the amplifier system, for example in the form of a resonant cavity or a resonant ring circuit. The beam propagation may occur in a single direction of propagation or both.

In a currently preferred embodiment with optical transmission in free space, the amplifier stages, including one or more interferometric optical amplification arrangements, comprise beam splitting and combining means, respectively at the input and output of each interferometric optical amplifier stage, for example optics devices made as prisms or semitransparent mirrors, and the return optical path comprises reflecting and refracting optical systems adapted to guide and spatially shape the beam. Alternatively, in an embodiment in guided or integrated optics, the optical beams are conducted by confinement in optical guides obtained on a substrate, for example a substrate compatible with the implementation of a semiconductor optical amplifier, and the division and recombination of the optical beams takes place through beam splitting and combining means obtained by means of controlled modal coupling techniques between the aforementioned optical guides.

The advantage of the interferometric amplifier structure lies in the possibility of diverting a portion of the incident optical power from the amplification branch in such a way as to prevent the occurrence of a saturation condition of the active region of the optical amplifier, which would limit its amplification properties.

With respect to a simple semiconductor optical amplifier, a semiconductor interferometric optical amplifier may have a lower gain but has a higher saturation power. The behavior of the interferometric amplifier moves further and further away from the behavior of a simple amplifier, as the greater the portion of the incident beam conducted through the non-amplifying propagation branch, the greater the gain through the amplification branch that operates far from the point of saturation. Furthermore, there are fewer phenomena associated with the power that degrade the overall performance of the device, thereby achieving greater stability and longer life.

In the configuration of the amplifier system described above, a portion of the emerging combined beam is extracted from the beam combining means at the output of the last interferometric optical amplifier stage and is delivered as the output radiation of the laser device of the invention, while the remaining portion of the emerging combined beam circulates in the resonant structure to give rise to laser oscillation. Thus, in this design, the beam combining means also simultaneously perform the role of output coupler means of the resonant structure. For example, the portion of the beam emerging from the amplifier system delivered as the output laser radiation is a loss beam of the beam combining means, whereby the major portion of the combined beam emerging from the amplifier system is reintroduced therein and amplified again.

In an alternative embodiment, the output coupler means are arranged at the end of the optical return path of the interference beam, at the input of the amplifier system (of the gain means) and are obtained as beam splitting means adapted to extract a minimum portion of the beam from the beam circulating in the resonant structure to deliver it as output laser radiation.

The portion of the beam that contributes to the radiation output of the laser device, i.e., the percentage of optical power extracted as the laser output, Pₒᵤₜ, with respect to the circulating power, P_{b}, is related to the circulating power through the reflectivity parameter R of the output coupler means. Depending on the position of the output coupler means in the resonant structure it may be

Pₒᵤₜ=R·P_{b}

or, vice versa,

Pₒᵤₜ=(1-R)·P_{b}

Typically, there is an optimal value of R which depends on the characteristics of the resonant structure, with particular reference to the losses that the beam undergoes during its propagation.

The configuration subject of the invention allows for a stationary condition of equilibrium between losses (output of the laser device), gain and interference between the recombined beams in each interferometric optical amplification arrangement to be attained. The division ratio of the beam splitting means and the optical lengths of the respective amplification and non-amplifying propagation branches of each interferometric arrangement are selected and controlled in such a way as to optimize the overall performance of the device, including the spectral separation between the interference maximums between the recombined beams. In effect, in real construction and operating conditions, wherein the optical path difference between the two branches is not zero, an interference spectrum is generated between the combined beams and the power of the combined beams corresponds to the average value between the maximum and the minimum of the power of the interfering beams. The spectral separation between two maximums or two minimums of interference depends on the difference in the optical path traveled by the two interfering beams.

Theoretically, by stabilizing the resonant structure, i.e., by forcing the phase difference between the beams conducted through the amplification branch and through the non-amplifying propagation branch to zero, the performance of a single interferometric amplification arrangement would be equivalent to (or even exceed) the performance of a standard non-interferometric laser diode, i.e., an external-cavity semiconductor laser diode. In effect, with respect to an external-cavity semiconductor laser diode, it is possible to obtain a reduction of the power on the gain means. Since this operates in the saturation regime, in an operating condition of lower incident optical power, the gain is greater.

The result of simulations conducted by the inventors has shown that the power output from a laser device according to the invention with two gain interferometric stages is greater than the (incoherent) sum of the power of two individual laser devices, and more generally that the power output from a laser device according to the invention at n interferometric gain stages is greater than the (incoherent) sum of the power of n individual laser devices.

Advantageously, by virtue of the proposed design, it is possible to obtain a coherent beam of high optical power without needing to carry out difficult techniques for controlling the phase of each laser-emitting device. However, the adoption of frequency stabilization techniques for the real-time and active control of the phase that the beam acquires during propagation, for example by imposing a control on the phase in the gain means or by creating a delay line, or resorting to a Pound-Drever-Hall stabilization for which the oscillation of a single wavelength corresponding to the maximum interference between the beams of the amplification branch and the non-amplifying branch is forced in the resonant structure, would allow a further increase in power and a narrower emission band.

Further features and advantages of the invention will be presented in greater detail in the following detailed description of an embodiment thereof, given by way of non-limiting example, with reference to the accompanying drawings, wherein:

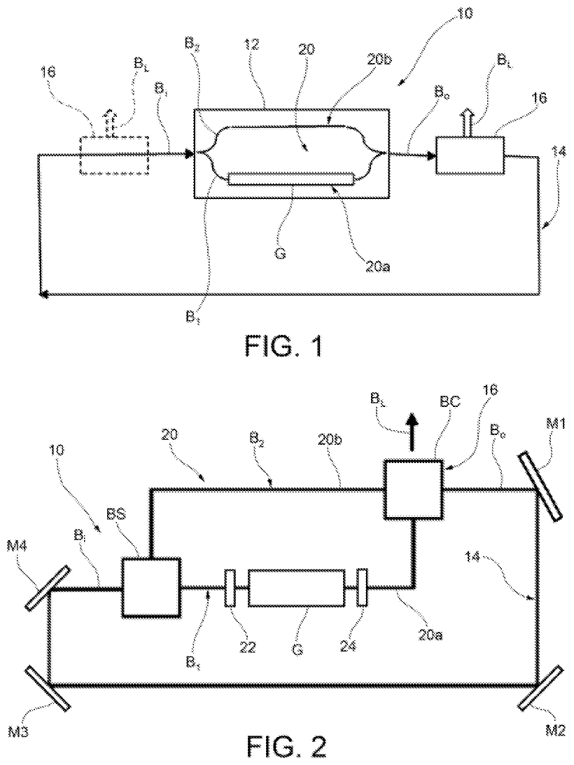

FIG. 1 is a general diagram of a laser device according to the invention;

FIG. 2 is a first schematic embodiment of a laser device according to the invention having a single interferometric optical amplification arrangement, in a free-space embodiment;

FIG. 3 shows a variant embodiment of the laser device of FIG. 2;

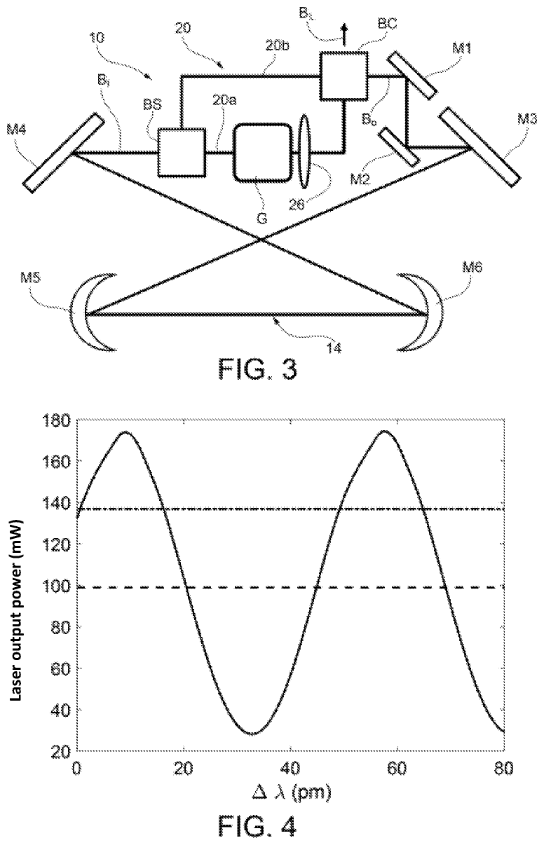

FIG. 4 is a simulation diagram of the behavior of the laser device of FIG. 3;

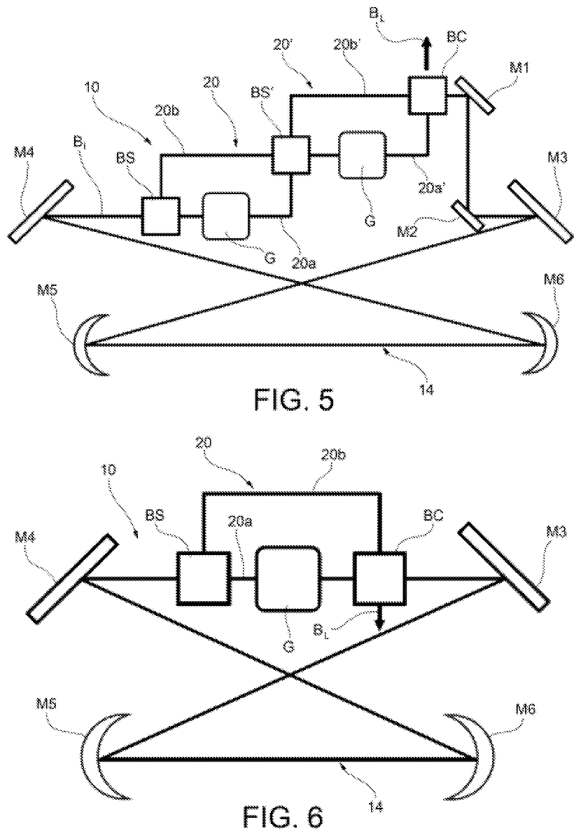

FIG. 5 shows the variant embodiment of the laser device of FIG. 3 with two cascaded interferometric optical amplification arrangements;

FIG. 6 is a second schematic embodiment of a laser device according to the invention having a single interferometric optical amplification arrangement, in a free-space embodiment;

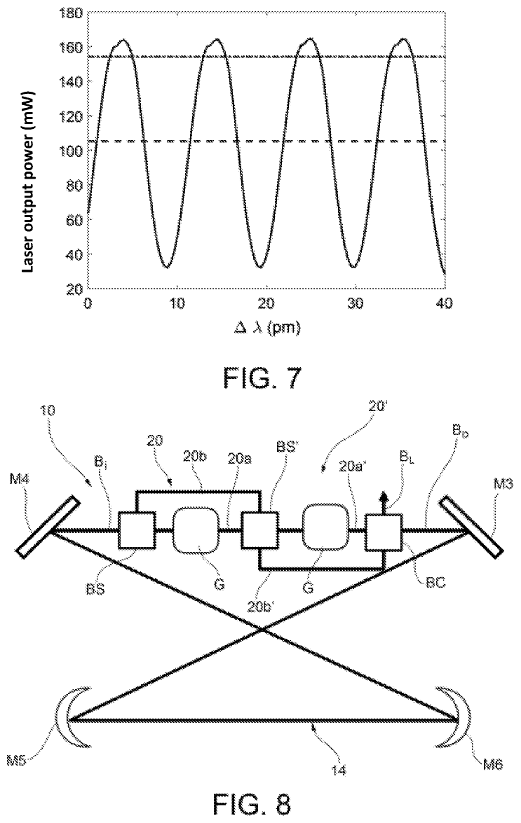

FIG. 7 is a simulation diagram of the behavior of the laser device of FIG. 6;

FIG. 8 shows the second embodiment of the laser device of FIG. 6 with two cascaded interferometric optical amplification arrangements;

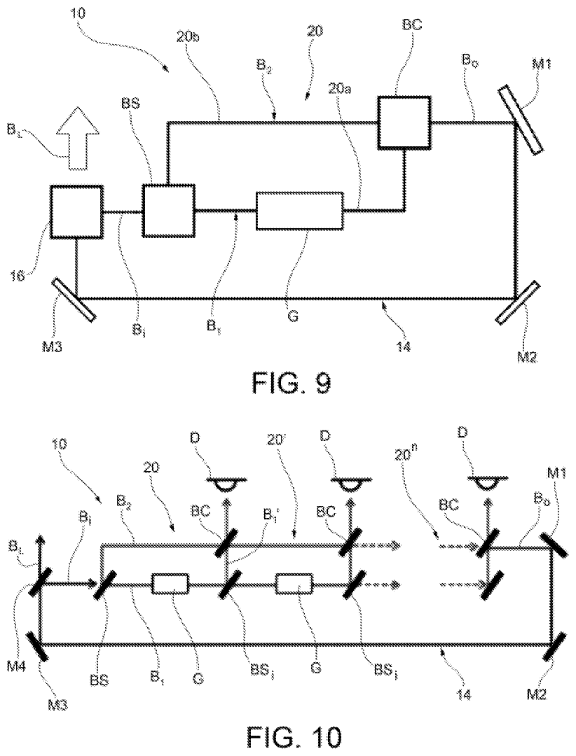

FIG. 9 shows a third embodiment of a laser device according to the invention having a single interferometric optical amplification arrangement, in a free-space embodiment; and

FIG. 10 shows the third embodiment of the laser device of FIG. 9 with a plurality of cascaded interferometric optical amplification arrangements.

FIG. 1 schematically shows in the essential aspects a laser device according to the invention, indicated collectively with 10. It comprises an amplifier system 12 of an incident optical beam Bᵢ, an optical return path 14 of an optical beam Bₒ emerging from the amplifier system 12 adapted to carry the optical beam Bₒ to the input of the amplifier system 12 as an incident optical beam Bᵢ and forming an optical resonant structure with the amplifier system 12, and means 16 for the output of a coherent optical radiation from the laser device adapted to extract a portion of the beam emerging from the amplifier system—or, alternatively (represented by a dashed line), a portion of the incident beam entering the amplifier system—and emitting said beam portion as output laser radiation B_{L}.

The amplifier system 12 comprises a single interferometric optical amplification arrangement 20 or a plurality of interferometric optical amplification arrangements 20 in series or cascade, as schematically represented in the block 12. Each interferometric optical amplification arrangement 20 includes input beam splitting means, adapted to spatially split the incident optical beam in a first beam portion B₁ and a second beam portion B₂, downstream of which the first beam portion B₁ is directed into an amplification arm 20a and the second beam portion B₂ is directed into a non-amplifying propagation arm 20b. Beam combining means, different from the input beam splitting means, are adapted to bring together the first portion of the amplified beam coming from the amplification arm 20a and the second portion of the beam propagated without amplification coming from the propagation arm 20b of each interferometric optical amplification arrangement 20, thus substantially forming a Mach Zehnder interferometric arrangement, and the combining means of the last optical interferometric amplification arrangement of the series form the optical beam Bₒ emerging from the amplifier system 12.

The amplification arm 20a includes an active region or gain region G capable of emitting photons coherent with the first portion of the beam B₁ by stimulated emission following the excitation obtained, for example, by means of optical or electrical pumping.

In a currently preferred embodiment, the active region includes a semiconductor material, and an electrical excitation system is associated therewith, adapted to alter the thermodynamic equilibrium of the charge carrier populations confined therein, in order to determine an inversion condition of the charge carrier population and consequent radiative recombination.

In an alternative embodiment, the active region may include another material capable of supporting a stimulated emission of photons following optical or electrical excitation.

FIG. 2 shows a first schematic embodiment of a laser device according to the invention having a single interferometric optical amplification arrangement 20, in a free-space embodiment.

The interferometric optical amplification arrangement 20 includes at the input means BS for splitting the incident beam Bᵢ in the first beam portion B₁ and in the second beam portion B₂, and at the output combining means BC of the first beam portion B₁ amplified in the active gain region G and the second beam portion B₂. The combined optical beam Bₒ emerging from the interferometric optical amplification arrangement 20 is returned at the input to the same interferometric optical amplification arrangement 20 through an optical return path 14 forming an optical resonant ring structure, comprising optical reflector means, in the non-limiting example, four flat mirrors M1-M4.

In an embodiment wherein the active gain region G of the amplification branch is formed by an optical semiconductor amplifier, it is expedient to associate thereto an input beam coupling stage 22 and an output beam collimation stage 24, which may alternatively be obtained by:
a pair of aspherical lenses, respectively a first lens adapted to focus the beam entering the amplification region and a second lens adapted to collimate the beam exiting the amplification region;
a pair of aspherical lenses and a pair of cylindrical lenses to circularize the beam, respectively first lenses adapted to focus and circularize the beam entering the amplification region and second lenses adapted to circularize and collimate the beam exiting the amplification region;
a pair of spherical lenses and a pair of anamorphic prisms, respectively entering the amplification region and exiting the amplification region;
an aspherical lens for focusing the beam entering the amplification region and a pair of cylindrical lenses to collimate and circularize the beam exiting the amplification region;
a pair of micro-lenses, respectively for focusing and collimating the beam entering the amplification region and exiting the amplification region;
a micro-lens for focusing the beam entering the amplification region and a pair of micro-lenses to collimate the beam exiting the amplification region both in the slow axis and in the fast axis.

The propagation arm 20b may comprise one or more reflecting or refracting optical elements (not shown), respectively for controlling the optical length of the propagation path and for controlling the spatial shape of the beam.

The combining means BC at the output of the interferometric amplification arrangement 20 further form the output means 16 of the coherent optical radiation from the laser device (B_{L}) by extracting a portion of the beam Bₒ emerging from the arrangement 20 as a loss beam of said combining means.

FIG. 3 shows a variant embodiment of the laser device of FIG. 2 wherein the return optical path 14 comprises four flat mirrors M1-M4 and two curved mirrors M5, M6 for folding and shaping the beam.

The figure also shows an optical isolator 26 downstream of the active region G, adapted to allow the propagation of the first portion of the amplified beam in a single predetermined direction. The isolator 26 may be present in any other embodiment described and arranged at any point of the resonant structure. However, since the gain means G emits from both directions, for simplicity of alignment the isolator is advantageously arranged at the output of the active amplification region.

FIG. 4 is a simulation diagram of the behavior of the laser device of FIG. 3, which shows its output power as a function of the spectral window with respect to the origin of the graph. Specifically, the graph shows the result due to the interference between the two beams (amplified and unperturbed). The fringes are due to the interference between the first beam portion B₁ amplified in the active gain region G of the arm 20a and the second beam portion B₂ propagated without amplification in the arm 20b. The spacing between the fringes depends on the optical path. The dashed line indicates the average power, while the dotted line indicates the maximum power that may be extracted from a resonant structure having the same dimensions, but without interferometric arrangement of the propagation branch.

In the interference maximum the device of the invention shows better performances than a standard laser diode without interferometric arrangement. However, given the difficulty of balancing an interferometric arrangement, i.e., given the impossibility of making the optical paths in the two branches equal, the resulting output power is the average value of that which is shown in the graph.

FIG. 5 shows the variant embodiment of the laser device of FIG. 3 with two cascaded interferometric optical amplification arrangements 20, 20′, connected by beam splitting means BS' which actuate both the recombination of the beams of the interferometric amplification arrangement 20 upstream and the separation of the beams in the interferometric amplification arrangement 20′ downstream. This variant embodiment makes it possible to adopt interferometric amplification arrangements in each of which the difference in optical length of the amplification and propagation arms 20a, 20b (20a′, 20b′ respectively) may be minimized, or such optical lengths made equivalent.

FIG. 6 is a second schematic embodiment of a laser device according to the invention having a single interferometric optical amplification arrangement, in a free-space embodiment. It shows a more compact structure wherein the beam splitting means BS and the beam combining means BC—different from the beam splitting means BS—are substantially aligned with the input paths of the incident beam Bᵢ and the output paths of the emerging beam Bₒ, to the detriment of the interference control between the first beam portion B₁ amplified in the active gain region G of the arm 20a and the second beam portion B₂ propagated without amplification in the arm 20b, the two arms 20a, 20b showing a significant difference in optical length.

FIG. 7 is a simulation diagram of the behavior of the laser device of FIG. 6, which shows its output power as a function of the spectral window with respect to the origin of the graph. Specifically, the graph shows the result due to the interference between the two beams (amplified and unperturbed). The fringes are due to the interference between the amplified beam and the unperturbed beam. The spacing between the interference fringes between the first beam portion B₁, amplified in the active gain region G of the arm 20a, and the second beam portion B₂, propagated without amplification in the arm 20b, depends on the optical path and is different with respect to the spacing between the fringes of the graph in FIG. 4 because the optical path is different: the narrower fringes correspond to a greater difference in the optical path traveled by the beams. The dashed line indicates the average power, while the dotted line indicates the maximum power that may be extracted from a resonant structure having the same dimensions, but without interferometric arrangement of the propagation branch.

FIG. 8 shows the second embodiment of the laser device of FIG. 6 with two cascaded interferometric optical amplification arrangements. With respect to the configuration of FIG. 5, this configuration is more compact in a free-space embodiment.

FIG. 9 shows a third embodiment of a laser device according to the invention having a single interferometric optical amplification arrangement, in a free-space embodiment.

Unlike the first and second embodiments, the means 16 for the output of the coherent optical radiation from the laser device are arranged to extract a portion of the beam conducted along the optical return path entering the amplifier system and to emit said beam portion as laser radiation at the output.

FIG. 10 shows the configuration of FIG. 9 with a plurality of cascaded interferometric optical amplification arrangements 20, 20′, . . . , 20′. The first interferometric optical amplification arrangement is substantially analogous to the interferometric optical amplification arrangement which characterizes the embodiments described above, except for the interposition of beam splitting means BSᵢ along the amplification arm, adapted to extract a smaller portion of the amplified beam to direct it toward the amplification arm of the subsequent downstream interferometric amplification arrangement, separately from a greater portion of the amplified beam directed toward the combiner means BC. Each intermediate interferometric optical amplification arrangement thus has at its input beam splitter means BSᵢ that act exclusively on the beam of the amplification arm 20a of the preceding interferometric stage, and not on the recombined beam of the preceding interferometric stage. The combining means BC of each interferometric optical amplification arrangement, different from the beam splitting means BSᵢ, brings together, and passes on to the next stage, the residual beam portion B₁′ amplified in the active gain region G, which is not transmitted to the amplification arm of the downstream arrangement, and the beam portion B₂ propagated without amplification. The combining means BC of each interferometric amplification arrangement may have a relative loss beam which is advantageously directed toward optical beam detector means D (for example, a photodiode) adapted to monitor the intensity and phase of the beam intermediate in the amplification chain.

The optical combined beam Bₒ emerging from the series of cascaded interferometric optical amplification arrangements of the amplification system is returned to the input of the first interferometric optical amplification arrangement of the amplification system through an optical return path 14 forming an optical ring resonant structure.

The laser device according to the invention offers various advantages with respect to the solutions offered by the state of the art. With respect to currently adopted incoherent beam combination techniques, the described device shows the advantages of a coherent combination technique. With respect to techniques for wavelength beam combination, it allows an increase in power to be obtained while maintaining the spectral quality of said laser. With respect to coherent beam combining architectures, it offers a robust tool that avoids the use of active real-time phase control algorithms for each laser-emitting device, making manufacturing and industrial adoption easier.

Furthermore, the implementation of a single resonant structure external to all the amplifier stages offers the possibility of controlling the spatial shape of the beam directly in the cavity.

From a theoretical point of view, the only limit on the number of cascaded interferometric amplification arrangements is given by the gain saturation law of the single optical amplifiers of the amplification branches.

It should be noted that the embodiment proposed for this invention in the foregoing discussion is purely by way of non-limiting example of this invention. A person skilled in the art will easily be able to implement this invention in different embodiments which do not however depart from the principles set forth herein and are therefore encompassed in this patent.

This is particularly true with regard to the possibility of constructing the beam splitting and combining means, the gain means and the resonant structure according to techniques or configurations different from those described or referred to above. For example, although the interferometric amplification arrangements have been shown with the amplification arm arranged along the direction of transmission of the incident beam on the beam splitting means and the non-amplifying propagation arm arranged along a direction of reflection or coupling of the incident beam on the beam splitting means, it is possible to invert the arrangements of the amplification and propagation arms with respect to the beam splitting means as long as the condition is respected that most of the optical power incident on the beam splitting means is directed toward the non-amplifying propagation branch.

A free-space embodiment of the device with a large number of gain means requires particular attention in the optical alignment of the components, and more expediently the device of the invention may be obtained—in part or in its entirety—with guided optics, including optical fiber systems or systems with semiconductor integrated optics or another platform (for example glass).

Naturally, without prejudice to the principle of the invention, the embodiments and the details of execution may vary widely with respect to that which has been described and illustrated purely by way of non-limiting example, without thereby departing from the scope of protection of the invention defined by the appended claims.

1-12. (canceled)

13. A laser device configured to emit a coherent optical radiation, comprising:
an amplifier system, comprising a single interferometric optical amplification arrangement or a plurality of interferometric optical amplification arrangements in series, wherein each interferometric optical amplification arrangement comprises input beam splitters adapted to spatially separate an incident optical beam into a first beam portion and a second beam portion, downstream of which an amplification arm of the first beam portion, comprising an active gain region capable of emitting photons coherent with the first beam portion, and a propagation arm without amplification of the second beam portion extend, which meet at an output of the interferometric optical amplification arrangement;
beam combining means different from said input beam splitters and adapted to gather the first beam portion amplified in the active gain region and the second beam portion propagated without amplification of the single interferometric optical amplification arrangement or of the last interferometric optical amplification arrangement of the plurality of interferometric optical amplification arrangements, into an optical beam emerging from the amplifier system;
a return optical path for the optical beam emerging from the amplifier system, comprising optical reflectors and configured to conduct said optical beam emerging from the amplifier system at an input to the amplifier system forming an optical ring resonant structure therewith; and
a radiation output for extracting a portion of the optical beam emerging from the amplifier system and deliver said portion of the optical beam emerging from the amplifier system as output laser radiation of the laser device,
wherein power of the first beam portion routed in the amplification arm is less than power of the second beam portion routed in the propagation arm without amplification.

14. The laser device of claim 13, wherein the amplification arm comprises an active gain region of semiconductor material capable of emitting photons coherent with the first beam portion following attainment of a population inversion condition of a population of charge carriers confined therein and consequent radiative recombination, said active gain region being associated with an electrical excitation system configured to alter a thermodynamic equilibrium of the population of charge carriers to determine said population inversion condition.

15. The laser device of claim 13, wherein in the plurality of interferometric optical amplification arrangements the input beam splitters are adapted to spatially separate interfering first beam portion and second beam portion of a preceding interferometric optical amplification arrangement.

16. The laser device of claim 13, wherein each intermediate interferometric optical amplification arrangement of said plurality of interferometric optical amplification arrangements comprises input beam splitters adapted to spatially split only the first beam portion of a preceding interferometric optical amplification arrangement, and not a recombined beam of the preceding interferometric optical amplification arrangement.

17. The laser device of claim 13, wherein said portion of the optical beam emerging from the amplifier system and delivered as output laser radiation of the laser device is a loss beam of said beam combining means adapted to bring together the first beam portion amplified in the active gain region and the second beam portion propagated without amplification into the optical beam emerging from the amplifier system.

18. The laser device of claim 13, wherein said portion of the optical beam emerging from the amplifier system and delivered as output laser radiation of the laser device is a loss beam of one of said optical reflectors of the return optical path.

19. The laser device of claim 13, wherein the amplification arm comprises an input beam coupling stage and an output beam collimation stage coupled to said active gain region, comprising a pair of dioptric systems arranged respectively to focus the first beam portion entering the active gain region and to collimate the first beam portion amplified in the active gain region and exiting the active gain region.

20. The laser device of claim 13, wherein the propagation arm without amplification comprises a catoptric system or a dioptric system configured to control addressing or distribution of transverse power of the second beam portion.

21. The laser device of claim 13, wherein said optical reflectors include a plurality of totally reflective catoptric systems.

22. The laser device of claim 13, wherein said return optical path comprises optical elements configured to shape distribution of transverse power of the beam emerging from the amplifier system.

23. The laser device of claim 13, wherein said optical ring resonant structure comprises an optical isolator configured to allow propagation of a beam in a single predetermined direction.

24. The laser device of claim 13, wherein an optical length of the amplification arm and an optical length of the propagation arm without amplification of each interferometric optical amplification arrangement are equivalent.
